(19) United States
(12) Patent Application Publication
(10) Pub. No.: US 2026/0206139 A1
(43) Pub. Date: Jul. 16, 2026

(54) MECHANICAL BONDING BETWEEN FLEX CIRCUITS

(71) Applicant: Manaflex, LLC, Waikoloa, HI (US)

(72) Inventors: Robert C. LANE, Las Vegas, NV (US); Yifei LIU, Toronto, Ontario (CA)

(21) Appl. No.: 19/331,057

(22) Filed: Sep. 17, 2025

Related U.S. Application Data
(60) Provisional application No. 63/698,904, filed on Sep. 25, 2024.

(51) Int. Cl. H05K 1/14

(52) U.S. Cl. CPC H05K 1/147

(57) ABSTRACT

The use of welding or soldering to provide a mechanical bonding between flex circuits. A flex circuit system includes a first flex circuit having a first material portion, a second flex circuit having a second material portion, and a coupling that connects the first flex circuit to the second flex circuit by connecting the first material portion to the second material portion.

### CROSS-REFERENCE TO RELATED APPLICATION

This patent application is a non-provisional application of, and claims priority to and the benefit of, U.S. patent application Ser. No. 63/698,904, filed Sep. 25, 2024, entitled “Mechanical Bonding Between Flex Circuits”, and having Attorney Docket No. 4375.0026P, the entire disclosure of which is incorporated by reference in its entirety.

### FIELD OF INVENTION

The present invention relates to flex circuits, and in particular to mechanical bonding between flex circuits.

### BACKGROUND

In conventional couplings of flex circuits, an adhesive or a double-sided tape is used to couple the flex circuits together. However, the use of an adhesive or a double-sided tape involves a high material cost.

Thus, there is a need for a more economical alternative for coupling flex circuits together. Also, there is a need for a better way to couple flex circuits together.

### SUMMARY

In one aspect, the present disclosure relates to the use of welding or soldering to provide a mechanical bonding between flex circuits.

In one implementation according to the present disclosure relates to a flex circuit system that comprises a first flex circuit having a first material portion, a second flex circuit having a second material portion, and a coupling that connects the first flex circuit to the second flex circuit by connecting the first material portion to the second material portion.

In one embodiment, the coupling is achieved by welding or soldering the first material portion to the second material portion.

In another embodiment, the coupling includes a first coupling portion and a second coupling portion.

In an alternative embodiment, the first material portion overlaps with the second material portion.

In yet another embodiment, each of the first material portion and the second material portion is formed of a metal material.

In one embodiment, the coupling is a first coupling, and the flex circuit system further comprises a second coupling connecting the first flex circuit to the second flex circuit, the second coupling being spaced apart from the first coupling.

In another embodiment, the first flex circuit has a third material portion, the second flex circuit has a fourth material portion, and the second coupling connects the third material portion to the fourth material portion.

In yet another embodiment, the third material portion overlaps with the fourth material portion.

In an alternative embodiment, the first material portion is electrically isolated from a remainder of the first flex circuit, and the second material portion is electrically isolated from a remainder of the second flex circuit.

### BRIEF DESCRIPTION OF THE DRAWINGS

To complete the description and in order to provide for a better understanding of the present application, a set of drawings is provided. The drawings form an integral part of the description and illustrate embodiments of the present application, which should not be interpreted as restricting the scope of the invention, but just as examples. The drawings comprise the following figures:

FIG. 1 illustrates a schematic drawing of an embodiment of a conventional coupling of flex circuits.

FIG. 2 illustrates a schematic drawing of an embodiment of a coupling of flex circuits according to an aspect of this disclosure.

FIG. 3 illustrates a top view of an embodiment of a coupling of flex circuits according to an aspect of this disclosure.

FIG. 4 illustrates a close-up to view of an embodiment of a coupling of flex circuits according to an aspect of this disclosure.

Like reference numerals have been used to identify like elements throughout this disclosure.

### DETAILED DESCRIPTION

The following description is not to be taken in a limiting sense but is given solely for the purpose of describing the broad principles of the invention. Embodiments of the invention will be described by way of example, with reference to the above-mentioned drawings showing elements and results according to the present invention.

In one aspect of the present disclosure, the techniques relate to the use of welding or soldering to provide a mechanical bonding between flex circuits.

An advantage of the present invention is that it simplifies the assembly and process.

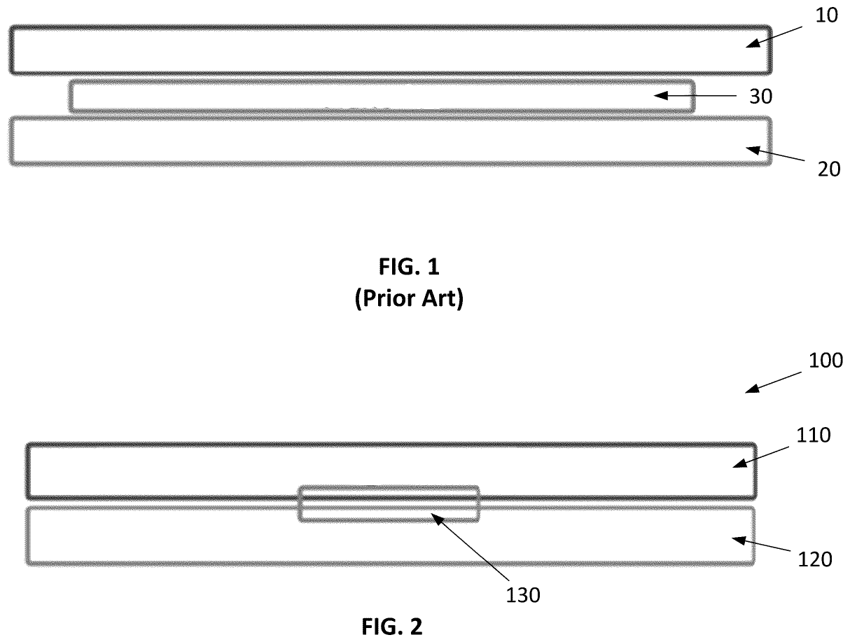

Turning to FIG. 1, a schematic drawing of an embodiment of a conventional coupling of flex circuits is illustrated. As shown, flex circuit 10 is coupled to flex circuit 20 using an adhesive 30. The illustrated traditional or conventional method of bonding and stacking different flex circuits 10 and 20 uses an adhesive 30 (or alternatively double-sided tapes) to constrain the two circuits 10 and 20 together. Devising a method to avoid using an adhesive or adhesive-type material can be a cost reduction and an overall improvement.

In one embodiment of a coupling of flex circuits, the present disclosure relates to the removal of the adhesive. The adhesive is replaced by using welding or soldering to bond the metal layers between the flex circuits. The method disclosed herein uses the pre-existing material in the flex circuits for the coupling of adjacent flex circuits together. As a result, the method and structure according to the present disclosure saves the additional material cost of adhesives.

Referring to FIG. 2, a schematic drawing of an embodiment of a flex circuit system including the coupling of flex circuits according to an aspect of this disclosure is illustrated. As shown, the flex circuit system 100 includes a flex circuit 110 that is coupled to another flex circuit 120 via coupling 130. In this embodiment, the coupling 130 is achieved by welding or soldering.

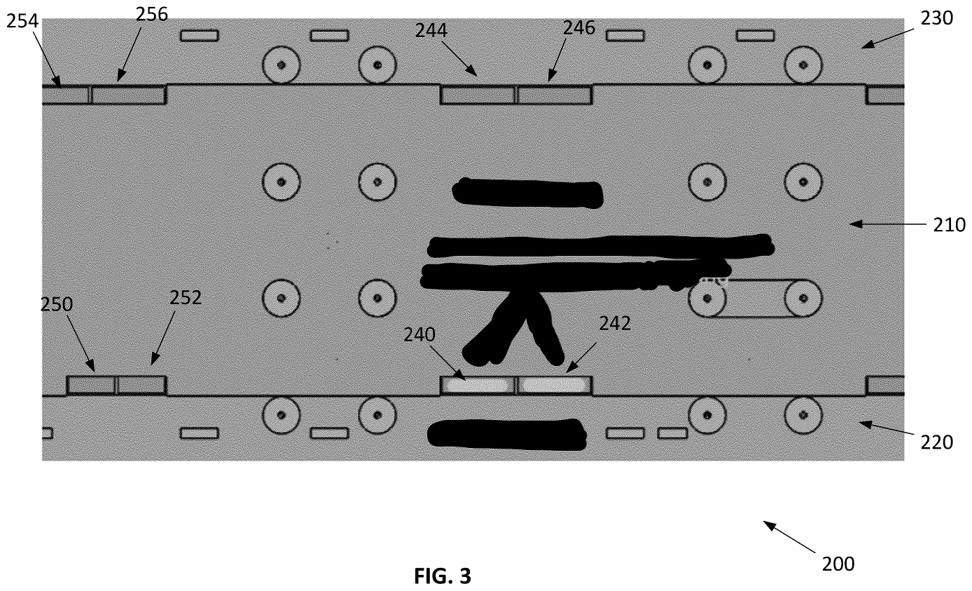

Turning to FIG. 3, a top view of an embodiment of a flex circuit system including the coupling of flex circuits according to an aspect of this disclosure is illustrated. Flex circuit system 200 includes a flex circuit 210 that is coupled to another flex circuit 220. In this embodiment, flex circuit 210 is coupled to flex circuit 220 via coupling portions 240 and 242 and via coupling portions 250 and 252, which are made for a flex circuit-to-flex circuit mechanical coupling, such as welding or soldering. Each of the coupling portions 240, 242, 250, and 252 is formed by a specific section, such as a first material portion, on flex circuit 210 and a specific section, such as a second material portion, on flex circuit 220. For coupling portion 240, the specific section (a first material portion) on flex circuit 210 and the specific section (a second material portion) on flex circuit 220 are formed of a metal material and are positioned to overlap each other, thereby permitting those specific sections to be coupled together by welding or soldering. Similarly, for each of the other coupling portions 242, 250, and 252, the respective specific section on flex circuit 210 and the respective specific section on flex circuit 220 are also formed of a metal material and are positioned to overlap each other, thereby permitting those specific sections to be coupled together by welding or soldering. The flex circuits 210 and 220 may have several additional spaced-apart coupling portions which are different material portions of the different flex circuits 210 and 220.

Flex circuit system 200 includes another flex circuit 230 that is coupled to flex circuit 210. In this embodiment, flex circuit 210 is coupled to flex circuit 230 via coupling portions 244 and 246 and via coupling portions 254 and 256, which are made for a flex circuit-to-flex circuit mechanical coupling, such as welding or soldering. Each of the coupling portions 244, 246, 254, and 256 is formed by a specific section, such as a first material portion, on flex circuit 210 and a specific section, such as a second material portion, on flex circuit 230. For coupling portion 244, the specific section on flex circuit 210 and the specific section on flex circuit 220 are formed of a metal material and are positioned to overlap each other, thereby permitting those specific sections to be coupled together by welding or soldering. Similarly, for each of the other coupling portions 246, 254, and 256, the respective specific section on flex circuit 210 and the respective specific section on flex circuit 230 are also formed of a metal material and are positioned to overlap each other, thereby permitting those specific sections to be coupled together by welding or soldering. The flex circuits 210 and 230 may have several additional spaced-apart coupling portions which are different material portions of the different flex circuits 210 and 230.

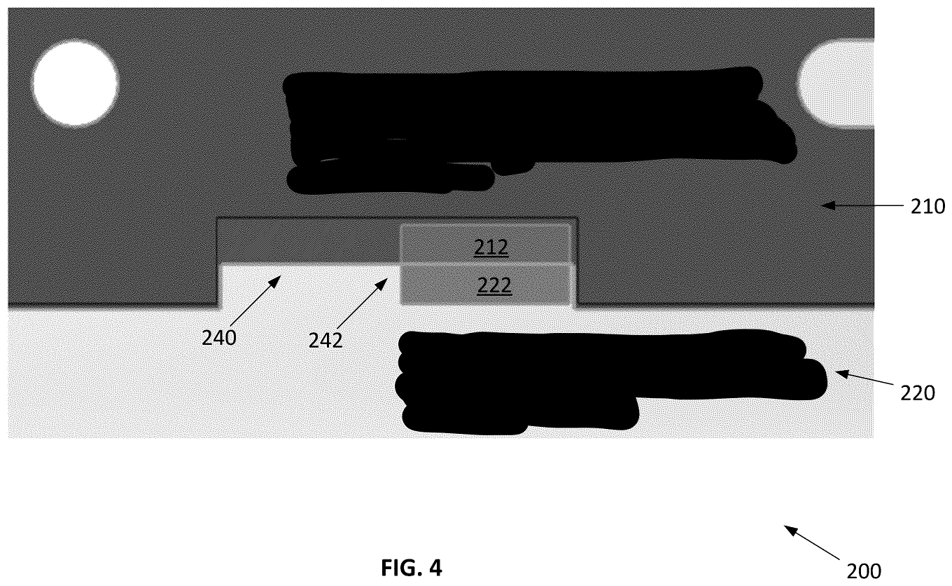

Turning to FIG. 4, a close-up to view of a portion of the flex circuit system 200 showing the coupling of flex circuits according to an aspect of this disclosure is illustrated. In this view, coupling portions 240 and 242 for flex circuits 210 and 220 are illustrated. Flex circuit 210 has a section 212 that is coupled to section 222 of flex circuit 220. Sections 212 and 222 are electrically isolated from the remainders of the respective flex circuits 210 and 220. As a result, any welding or soldering process does not introduce an electrical concern. Sections 212 and 222 are used for a mechanical circuit-to-circuit bond of flex circuits 210 to 220 using welding or soldering. Flex circuit 230 includes a similar section to sections 212 and 222 that is used for the coupling process.

It should be noted that in this document, the terms “comprising,” “including,” or any other variants thereof, are intended to encompass non-exclusive inclusion, so that processes, methods, articles, or devices comprising a series of elements include not only those elements explicitly listed, but also other elements not explicitly listed, or even elements inherent to such processes, methods, articles, or devices. In the absence of further limitations, the elements limited by the phrase “including one . . . ” do not exclude other identical elements in processes, methods, articles, or devices including the specified elements.

What is claimed is:

1. A flex circuit system, comprising:
a first flex circuit having a first material portion;
a second flex circuit having a second material portion; and
a coupling that connects the first flex circuit to the second flex circuit by connecting the first material portion to the second material portion.

2. The flex circuit system of claim 1, wherein the coupling is achieved by welding or soldering the first material portion to the second material portion.

3. The flex circuit system of claim 1, wherein the coupling includes a first coupling portion and a second coupling portion.

4. The flex circuit system of claim 1, wherein the first material portion overlaps with the second material portion.

5. The flex circuit system of claim 4, wherein each of the first material portion and the second material portion is formed of a metal material.

6. The flex circuit system of claim 1, wherein the coupling is a first coupling, and the flex circuit system further comprises:
a second coupling connecting the first flex circuit to the second flex circuit, the second coupling being spaced apart from the first coupling.

7. The flex circuit system of claim 6, wherein the first flex circuit has a third material portion, the second flex circuit has a fourth material portion, and the second coupling connects the third material portion to the fourth material portion.

8. The flex circuit system of claim 7, wherein the third material portion overlaps with the fourth material portion.

9. The flex circuit system of claim 1, wherein the first material portion is electrically isolated from a remainder of the first flex circuit, and the second material portion is electrically isolated from a remainder of the second flex circuit.
